(19) United States
(12) Patent Application Publication
(10) Pub. No.: US 2025/0357092 A1
(43) Pub. Date: Nov. 20, 2025

(54) SUBSTRATE PROCESSING APPARATUS

(71) Applicant: Samsung Electronics Co., Ltd., Suwon-si (KR)

(72) Inventors: Young-Tae CHOI, Suwon-si (KR); Jinuk PARK, Suwon-si (KR); Jonggun YOON, Suwon-si (KR)

(21) Appl. No.: 19/028,372

(22) Filed: Jan. 17, 2025

(30) Foreign Application Priority Data
May 14, 2024 (KR) 10-2024-0063258

(51) Int. Cl. H01J 37/32

(52) U.S. Cl. CPC H01J 37/32669; H01J 37/3244; H01J 2237/334

(57) ABSTRACT

Provided is a substrate processing apparatus including a chamber having a substrate processing space, a substrate support disposed in the chamber and configured to support a substrate, a gas injection unit disposed to be spaced apart from the substrate support and configured to supply a gas to the substrate processing space, and a magnet assembly disposed outside the chamber and configured to form a magnetic field in the chamber, and the magnet assembly includes one or more magnet holders including a plurality of openings or indentations, and a plurality of magnets received in at least one of the plurality of openings or indentations to maintain an interval between each other.

### CROSS-REFERENCE TO RELATED APPLICATION(S)

This application claims priority under 35 U.S.C. § 119 to and the benefit of Korean Patent Application No. 10-2024-0063258, filed on May 14, 2024, in the Korean Intellectual Property Office, the disclosure of which is incorporated herein by reference.

### BACKGROUND

### 1. Field of the Invention

The present disclosure relates to a substrate processing apparatus.

### 2. Description of the Related Art

Generally, a series of processes such as deposition, etching, or cleaning may be performed in order to manufacture a semiconductor device. Plasma technology such as capacitive coupled plasma (CCP) or inductive coupled plasma (ICP) may be applied to at least a portion of the processes.

A plasma is generated by a greatly high temperature, a strong electric field, or a radio frequency (RF) electromagnetic field and refers to an ionized gaseous state formed of an ion, an electron, a radical, or the like. For example, an etching process through the plasma technology may be performed by collision of ion particles contained in the plasma with a substrate.

Uniformity between a central area and an edge area of a wafer in a process may be required to be secured in manufacturing a semiconductor device through the plasma technology (e.g., a plasma process). In order to improve a characteristic of the plasma, an apparatus for adding a magnetic field to a plasma area is largely used.

However, related substrate processing apparatuses may have difficulty in precisely controlling a position, strength, and magnetic flux density of the magnetic field generated in the plasma area.

### SUMMARY

An aspect provides a substrate processing apparatus for controlling a formation position, strength, and magnetic flux density of a magnetic field in a chamber.

Another aspect provides a substrate processing apparatus for controlling magnetic flux density in a chamber to compensate deviations of process conditions depending on a change over time in an ion incidence angle.

However, the goals to be achieved by example embodiments of the present disclosure are not limited to the objectives described above and other objects may be clearly understood from the following example embodiments by those skilled in the art.

According to an aspect, there is provided a substrate processing apparatus including a chamber having a substrate processing space, a substrate support disposed in the chamber and configured to support a substrate, a gas injection unit disposed to be spaced apart from the substrate support and configured to supply a gas to the substrate processing space, and a magnet assembly disposed outside the chamber and configured to form a magnetic field in the chamber, and the magnet assembly includes one or more magnet holders including a plurality of openings or indentations, and a plurality of magnets received in at least one of the plurality of openings or indentations to maintain an interval between each other.

According to another aspect, there is also provided a substrate processing apparatus including a chamber having a substrate processing space configured to receive a substrate, a magnet assembly disposed outside the chamber, and a position adjustment unit configured to adjust an interval between the magnet assembly and the chamber, the magnet assembly includes a plurality of magnets configured to form a magnetic field in the substrate processing space, and one or magnet holders configured to receive the plurality of magnets.

According to still another aspect, there is also provided a substrate processing apparatus including a chamber having a substrate processing space, a substrate support disposed in the chamber, a gas injection unit disposed above the substrate support and configured to supply a gas to the substrate processing space, and a magnet assembly disposed outside the chamber, and the magnet assembly includes a plurality of magnet holders stacked in a vertical direction, and a plurality of magnets received in at least one of the plurality of magnet holders.

Additional aspects of example embodiments will be set forth in part in the following description and drawings.

According to example embodiments, it is possible to precisely control a formation position, strength, and magnetic flux density of a magnetic field in a chamber through a magnet assembly including receiving parts for receiving a plurality of magnets.

Also, according to example embodiments, it is possible to increase accuracy and efficiency of a process by controlling the magnetic flux density in the chamber by compensating deviations of process conditions depending on a change over time in an ion incidence angle.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates an example configuration of a substrate processing apparatus according to example embodiments;

FIG. 2 is a perspective diagram illustrating a magnet assembly according to example embodiments;

FIG. 3 is an example exploded perspective diagram illustrating a magnet assembly according to example embodiments;

FIG. 4 is an example exploded perspective diagram illustrating a magnet holder according to example embodiments;

FIG. 5 is an example exploded perspective diagram illustrating a magnet holder according to example embodiments;

FIG. 6A to FIG. 6C are cross-sectional diagrams illustrating various examples of stacking a magnet holder according to example embodiments;

FIG. 7A to FIG. 7C are reference diagrams illustrating various shapes of a magnet holder according to example embodiments;

FIG. 8 is an example exploded perspective diagram illustrating a magnet holder according to example embodiments;

FIG. 9 illustrates an example configuration of a substrate processing apparatus according to another example embodiment; and

FIG. 10 illustrates an example configuration of a substrate processing apparatus according to another example embodiment.

### DETAILED DESCRIPTION

Before example embodiments are described, it should be noted that terms or words used in the present disclosure and the accompanying claims are not to be limited to general definitions or dictionary definitions. The terms and words are to be construed under a principle that an inventor may appropriately define a concept of a term in order to describe their invention in the best way. Thus, since the example embodiments described in the present disclosure and configurations illustrated in the accompanying drawings are merely most desirable example embodiments and do not represent all of the technical spirit of the present disclosure, it should be understood that various equivalents and modifications that may replace the example embodiments and configurations may be present at the time of filing the application of the present disclosure.

In the following descriptions, terms in a singular form include terms a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. For example, spatially relative terms, such as “beneath,” “below,” “lower,” “above,” “upper,” “top,” “bottom,” “front,” “rear,” “vertical,” “horizontal,” and the like, may be used herein for ease of description to describe positional relationships, such as illustrated in the figures, for example. It will be understood that the spatially relative terms encompass different orientations of the device in addition to the orientation depicted in the figures. Shapes, sizes, or the like of elements in the drawings may be exaggerated for clearer description.

Hereinafter, a semiconductor processing apparatus according to the example embodiments will be described with reference to the drawings.

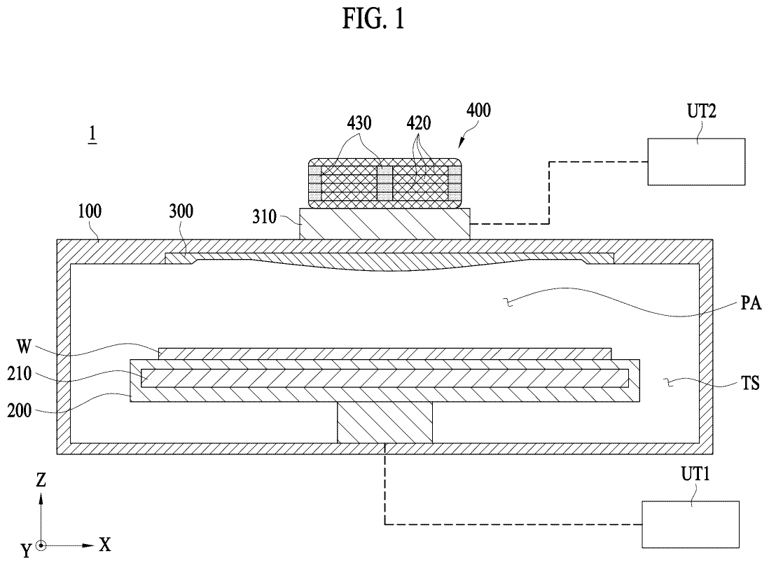

FIG. 1 illustrates an example configuration of a substrate processing apparatus 1 according to example embodiments.

The substrate processing apparatus 1 according to example embodiments may be an apparatus for performing a process such as deposition, etching, or cleaning by using a plasma. For example, the substrate processing apparatus 1 may be an apparatus for etching at least a portion (e.g., a thin film on a substrate) of a substrate W and may be a capacitively coupled plasma etching apparatus or an inductively coupled plasma etching apparatus. However, the substrate processing apparatus 1 is not limited to the above description and may be a chemical vapor deposition (CVD) apparatus or an atomic layer deposition (ALD) apparatus.

The substrate processing apparatus 1 according to example embodiments may include a chamber 100 having a substrate processing space TS, a substrate support 200 disposed in the chamber 100 and supporting the substrate W, and a gas injection unit 300 for supplying a process gas to the substrate processing space TS.

The chamber 100 may have therein an airtight space having a predetermined size. The airtight space may correspond to or be the same as the substrate processing space TS in which a semiconductor manufacturing process (e.g., a plasma etching process) is performed.

At least a portion of the substrate processing space TS of the chamber 100 according to example embodiments may be a plasma area PA. The plasma area PA may be a space in which the plasma is generated in a substrate processing process. For example, the plasma area PA may be formed in a space between the substrate support 200 and the gas injection unit 300. The gas injection unit 300 disclosed in the present disclosure may comprise one or more outlets, such as a showerhead, one or more nozzles, etc. to spray/inject/distribute a gas into the chamber 100.

The chamber 100 according to example embodiments may be formed in various shapes depending on a size (e.g., a diameter) of the substrate W or the like. For example, the chamber 100 may have a cylindrical or hexahedron structure. However, a shape of the chamber 100 is not limited thereto. Although not illustrated in the drawings, a substrate introduction port configured to open and shut may be disposed at one side of the chamber.

The substrate support 200 according to example embodiments may be disposed in a lower area in the chamber 100. The substrate W may be seated and supported on an upper surface of the substrate support 200.

The substrate support 200 according to example embodiments may include a lower electrode 210 electrically connected to a first supply UT1 and supplied with electricity. As used herein, components described as being “electrically connected” are configured such that an electrical signal can be transferred from one component to the other (although such electrical signal may be attenuated in strength as it is transferred and may be selectively transferred). For example, the first supply UT1 may be a power supply. The substrate W may be fixed in a state of being seated on the upper surface of the substrate support 200 by an electrostatic force. The lower electrode 210 may be supplied with radio frequency (RF) power from the first supply UT1.

The gas injection unit 300 according to example embodiments may be disposed in the chamber. The gas injection unit 300 may be disposed above the substrate support 200 to face the substrate support 200. The gas injection unit 300 may be connected to a second supply UT2 and configured to inject, into the substrate processing space TS in the chamber 100, the process gas which is supplied from the second supply UT2.

The gas injection unit 300 according to example embodiments may include an upper electrode for a plasma process. For example, at least a portion of the gas injection unit 300 may be formed of a metallic material to directly serve as the upper electrode. For example, a lower part surface (e.g., a lower/bottom surface) of the gas injection unit 300 may formed as a circular metallic injection plate including an injection port for injecting the process gas, and the metallic injection plate may function as the upper electrode.

The gas injection unit 300 according to example embodiments may be supplied with electricity and the process gas from the second supply UT2. For example, the second supply UT2 may provide electricity for generating the plasma to the upper electrode of the gas injection unit 300. For example, the second supply UT2 may include a power supply and a gas supply.

A gas block 310 for connecting the second supply UT2 and the gas injection unit 300 to each other may be disposed above the gas injection unit 300 according to example embodiments. The gas block 310 may be disposed on an upper part (e.g., on a top surface) of the chamber 100 and provide multiple gas supply paths communicating with (e.g., connected to) the gas injection unit 300. The gas block 310 may perform a function of evenly distribute, to an entire area of the gas injection unit 300, a gas supplied from the second supply UT2. For example, the gas block 310 may be formed of metal and/or nonmagnetic material having gas paths in it of which gas paths are connected to the second supply UT2 and the gas injection unit 300.

The lower electrode 210 of the substrate support 200 and the upper electrode of the gas injection unit 300 according to example embodiments may serve as a plasma generation apparatus for generating the plasma. For example, the lower electrode 210 of the substrate support 200 and the upper electrode of the gas injection unit 300 may receive the electricity from the first supply UT1 and the second supply UT2, respectively, to generate an electric field. Accordingly, at least a portion of the process gas in the plasma area PA may be converted into the plasma. However, selectively, the electricity may be applied to one of the upper electrode and the lower electrode 210, and the other one thereof may function as a grounding electrode.

The substrate processing apparatus 1 according to example embodiments may further include a magnet assembly 400 configured to apply a magnetic field into the chamber 100.

The magnet assembly 400 according to example embodiments may be disposed outside the chamber 100. For example, referring to FIG. 1, the magnet assembly 400 may be disposed above the gas block 310 and disposed to be spaced apart from the substrate W in a direction of a height of the chamber 100 or in a vertical direction. However, a position of the magnet assembly 400 is not limited to an illustration of FIG. 1. The magnet assembly 400 may be disposed anywhere outside the chamber 100 as far as the magnetic assembly 400 apply the magnetic field into the plasma area PA in the chamber 100 from the place.

The magnet assembly 400 of the substrate processing apparatus 1 according to example embodiments may include a plurality of magnets 430 from which the magnetic field is generated and one or more magnet holders 420 for receiving the plurality of magnets 430.

The magnetic field generated from the magnets 430 of the magnet assembly 400 according to example embodiments may be applied to the plasma area PA in the chamber 100 to offset horizontally directed acceleration, of ions in the plasma area PA, parallel to a surface of the substrate W and improve vertical directionality of the ions in the plasma area PA such that the ions move toward the surface of the substrate W. Accordingly, in the plasma process which is performed by the substrate processing apparatus 1, perpendicularity of an etching profile (e.g., vertical etch profile) may be improved.

In the magnet assembly 400 according to example embodiments, the number of the magnet holders 420 and the number of the magnets 430 received in the respective magnet holders 420 may be appropriately adjusted. For example, the magnet holders 420 may have a stack structure in the magnet assembly 400, and strength and magnetic flux density of the magnetic field in the chamber 100 may be minutely adjusted by adjusting a stack quantity thereof. For example, the strength and the magnetic flux density of the magnetic field in the chamber 100 may be minutely adjusted by adjusting a quantity of the magnets 430 which are disposed into a magnet holder 420 forming each layer of the magnet assembly 400. Thus, etching uniformity and/or etching precision may be improved by precisely controlling a proceeding path of a plasma ion.

Also, since the substrate processing apparatus 1 according to example embodiments may precisely control travelling of an ion in the chamber 100 through the magnet assembly 400, the gas injection unit 300 for injecting the process gas may be prevented from being damaged due to collision with the ion.

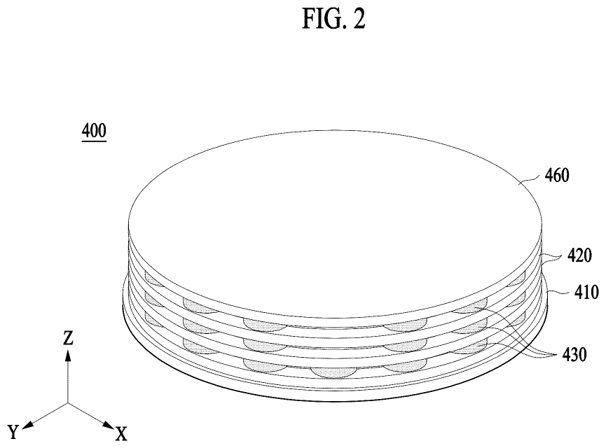

Hereinafter, the magnet assembly 400 of the substrate processing apparatus 1 may be described in detail with reference to FIGS. 2 to 7.

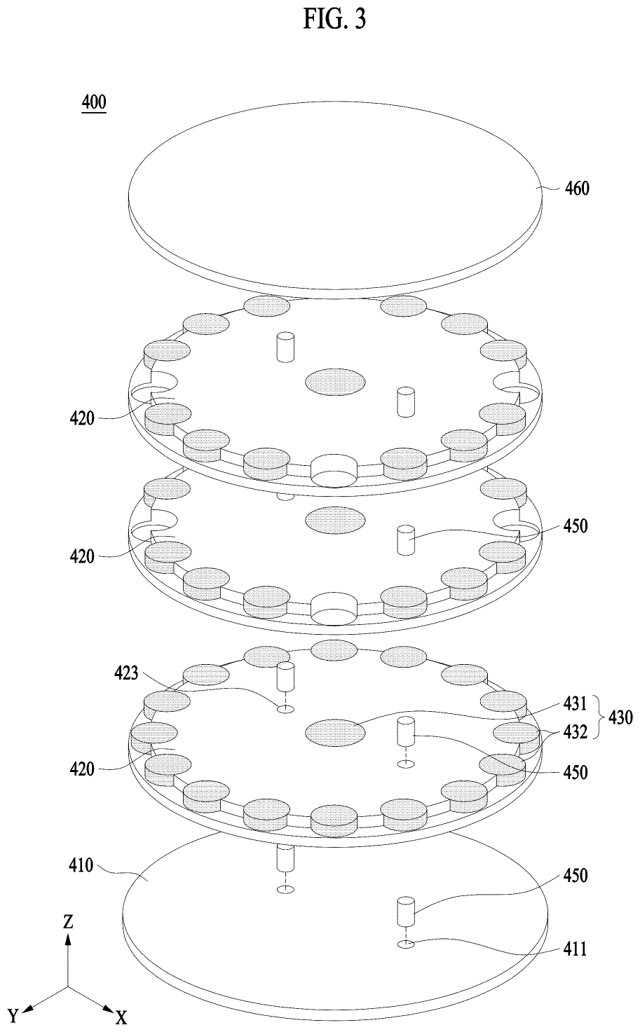

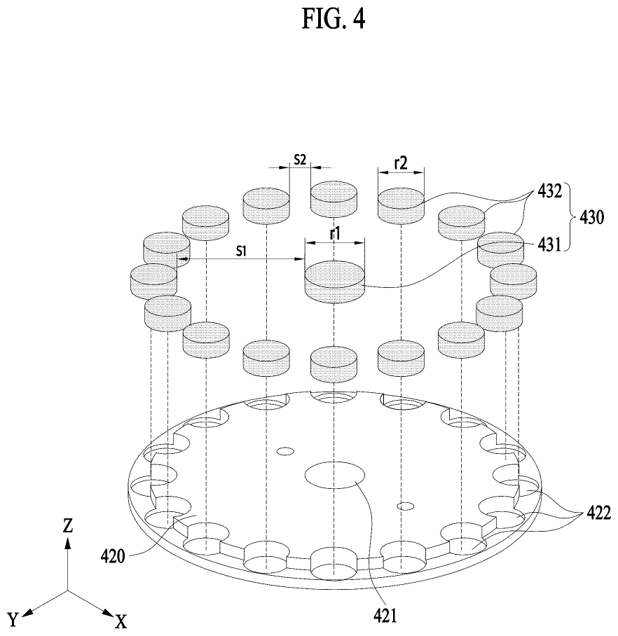

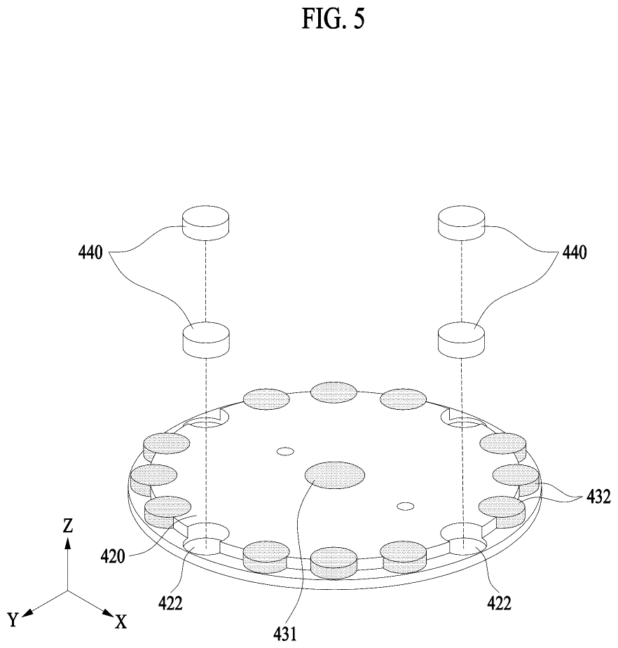

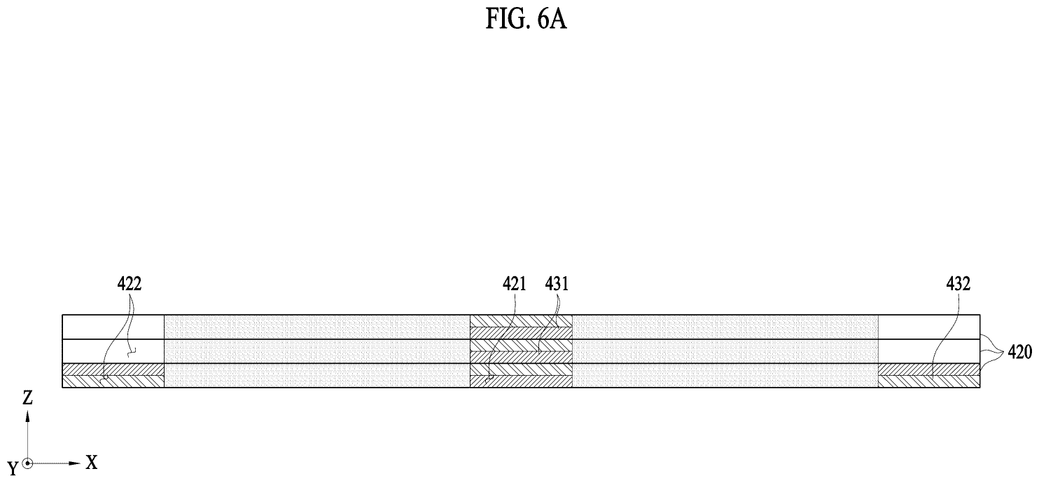

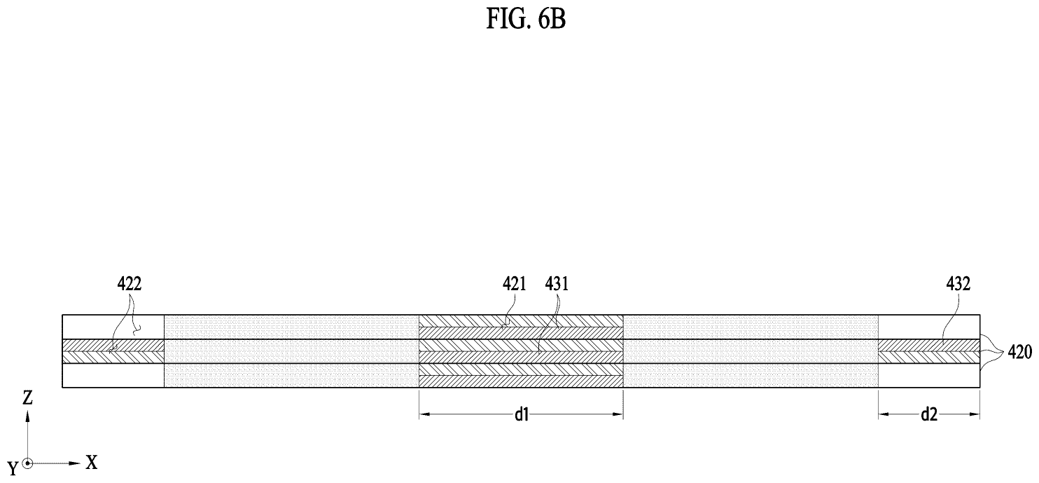

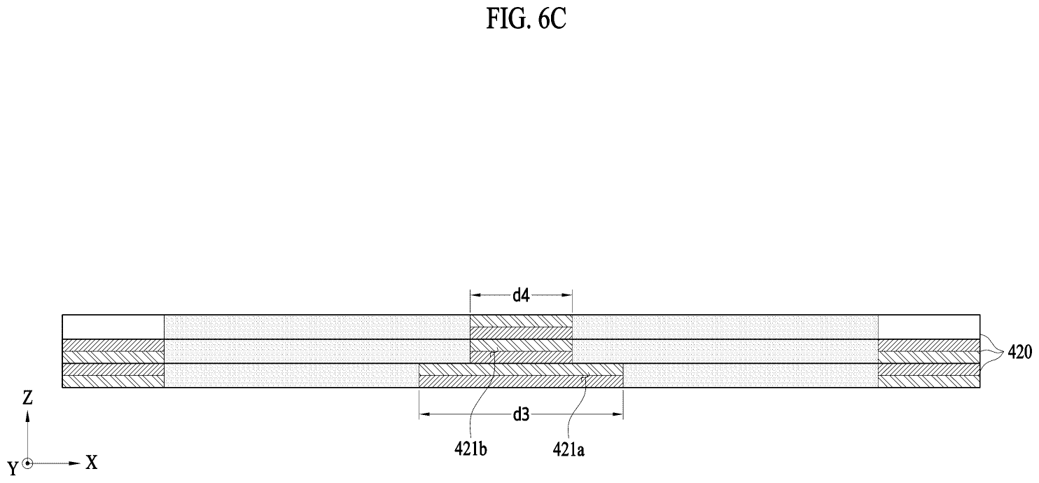

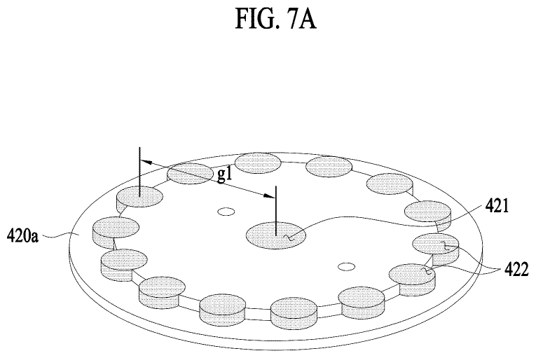

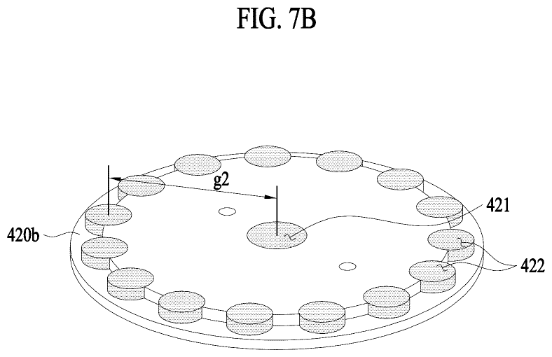

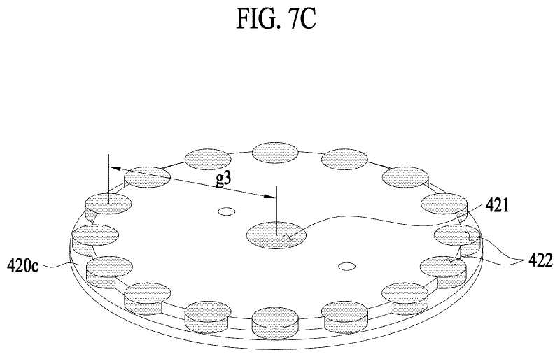

FIG. 2 is a perspective diagram illustrating the magnet assembly 400 according to example embodiments. FIG. 3 is an example exploded perspective diagram illustrating the magnet assembly 400 according to example embodiments. FIG. 4 is an example exploded perspective diagram illustrating the magnet holder 420 according to example embodiments. FIG. 5 is an example exploded perspective diagram illustrating the magnet holder 420 according to example embodiments. FIG. 6A to FIG. 6C are cross-sectional diagrams illustrating various examples of stacking the magnet holder 420 according to example embodiments. FIG. 7A to FIG. 7C are reference diagrams illustrating various shapes of the magnet holder 420 according to example embodiments.

The magnet assembly 400 which is described in FIGS. 2 through 7 corresponds to the magnet assembly 400 which is described in FIG. 1. A shape/structure of the magnet assembly 400 may be described with a focus on FIGS. 2 through 3, and redundant descriptions may be omitted.

The magnet assembly 400 may include the one or more magnet holders 420 which are configured to receive the plurality of magnets 430, a base 410 for supporting the magnet holders 420, and a cover 460 for covering an upper surface of the magnet holders 420. For example, the cover 460 may cover and/or vertically overlap magnet holders 420 stacked in a vertical direction.

In example embodiments, the magnet holders 420 may be configured to fix relative positions of the received plurality of magnets 430. For example, referring to FIGS. 2 through 4, each of the magnet holders 420 may include a plurality of receiving parts 421 and 422 having a groove/hole structure corresponding to a shape of a magnet 430 (or a size of the magnet 430). For example, the receiving parts 421/422 may be holes (e.g., receiving holes) formed in the magnet holders 420. For example, the receiving parts 421/422 may be through holes (openings) formed in the magnet holders 420, e.g., having cylindrical shapes. Alternatively, bottoms of the receiving parts 421/422 may be closed and the receiving parts 421/422 may form depressions (grooves/indentations). In certain embodiments, bottoms of the receiving parts 421/422 may be partially closed (e.g., in a circumferential area along a sidewall of the cylindrical shape) and partially open (e.g., in a central area). The magnets 430 may be inserted into the respective receiving parts 421 and 422, and a mutual position thereof may be fixed. For example, relative positions of the magnets 430 to each other may be determined when the magnets 430 are received in the respective receiving parts 421/422.

In example embodiments, the receiving parts 421 and 422 may include a first receiving part 421 and a second receiving part 422 that are disposed at different positions in the magnet holder 420. For example, referring to FIG. 4, the first receiving part 421 may be disposed on a central axis of the magnet holder 420, and a plurality of second receiving parts 422 including the second receiving part 422 may be disposed annularly along an edge of the magnetic holder 420, e.g., in/along a circumferential direction of/around the central axis. Here, the central axis may be an axis extending in a direction perpendicular to the upper surface of the magnet holders 420 (e.g., a Z-axis/vertical direction in FIG. 4) at a center of the magnet holders 420. In this case, a position at which the first receiving part 421 is dispose may be a central area of the magnet holder 420 and a position overlapping, in a direction of a height of the substrate processing apparatus 1 (e.g., Z-axis directions in FIGS. 2 through 4), a central area of the substrate W.

For example, the first receiving part 421 may be disposed in the central area of the magnet holder 420, and the second receiving part 422 may be disposed in an edge area of the magnet holder 420. Through this, flexibility of disposing the magnets 430 may be increased, and a distribution of a magnetic field in the chamber 100 may be minutely adjusted.

In example embodiments, one or more magnets 430 may be respectively received and fixed to at least one of the first receiving part 421 and the plurality of second receiving parts 422. Groove/hole diameters of the first receiving part 421 and the second receiving part 422 may be formed to correspond to diameters of the magnets 430 received in the corresponding receiving parts 421 and 422. For example, diameters of the magnets 430 may be substantially the same as (e.g., a little shorter or minimally shorter than) respective diameters of the receiving parts 421/422 such that each magnet 430 are well fit into its receiving part 421/422 in which the magnet 430 is received. Accordingly, the magnets 430 are fixed to the magnet holder 420 through a simple task of fitting the magnets 430 in the receiving parts 421 and 422, and distances between the magnets 430 may be well maintained at predetermined distances, and also, intervals between the magnets 430 may be uniformly maintained, e.g., between the magnets 430 received in second receiving parts 422 and/or between the magnet 430 received in the first receiving part 421 and each of the magnets 430 received in the second receiving parts 422.

For example, through the magnet holder 420 having the receiving parts 421 and 422 into which the magnets 430 are individually inserted, the substrate processing apparatus 1 according to example embodiments may stably maintain intervals between magnets 430 although a temporary imbalance occurs in a magnetic attractive force or a magnetic repulsive force of the magnets 430. Accordingly, since the magnets 430 are stably disposed in a state of being spaced apart from each other in a narrow space, magnetic flux density in the chamber 100 may be minutely adjusted to a level desired by a manufacturer (or a user).

In example embodiments, a diameter of the first receiving part 421 and a diameter of the second receiving part 422 may be variously formed. For example, the diameter of the first receiving part 421 may be larger than the diameter of the second receiving part 422. A diameter r1 of a magnet received in the first receiving part 421 (hereinafter referred to as a first magnet 431) may be larger than a diameter r2 of a magnet received in the second receiving part 422 (hereinafter referred to as a second magnet 432).

Alternatively, the plurality of second receiving parts 422 may include different types of receiving parts, e.g., having different diameters. For example, the plurality of second receiving parts 422 may include a second receiving part having a relatively large diameter and a second receiving part having a relatively small diameter. Accordingly, diameters of the receiving parts 421 and 422 may be variously formed. Through this, the magnets 430 may be disposed to one magnet holder 420 in various patterns, e.g., with various diameters and/or with various arrangements, and accordingly, strength and magnetic flux density of the magnetic field may be variously adjusted/controlled.

However, sizes of the receiving parts 421 and 422 in the magnet holder 420 are not limited to the above description. For example, diameters of the first receiving part 421 and the second receiving parts 422 may be set to be all equal, or the first receiving part 421 may be set to have a diameter smaller than those of the second receiving parts 422.

In example embodiments, the first magnet 431 and the second magnet 432 may be inserted into and supported by the receiving parts 421 and 422, respectively. Through this, an interval between the first magnet 431 and the second magnet 432 may be maintained. In this case, in a magnet holder 420 having a diameter of approximately 186 millimeters (mm), an interval S1 between the first magnet 431 and the second magnet 432 may be formed to be greater than or equal to approximately 80 mm, and an interval S2 between second magnets 432 may be formed to be greater than or equal to approximately 5.4 mm. However, a size of the magnet holder 420 and an interval between magnets 431 and 432 are not limited to the above description and may vary depending on a size of the substrate processing apparatus 1, a size of the substrate W, or required magnetic flux density.

Although not illustrated in the drawings, the magnet holder 420 may include a third receiving part (not illustrated) disposed between the first receiving part 421 and the second receiving part 422. For example, a plurality of third receiving parts may be provided and disposed between the first receiving part 421 and the second receiving parts 422 in/along a circumferential direction around the first receiving parts 421. In addition, a receiving part may be formed at various positions on the magnet holder 420 in certain embodiments.

In example embodiments, the first magnet 431 which is disposed in the first receiving part 421 and the second magnet 432 which is disposed in the second receiving part 422 may be disposed such that polarity directions thereof are opposite to each other. For example, referring to FIG. 4, when the first magnet 431 is disposed such that an N-pole thereof faces the gas injection unit 300 (of FIG. 1), the second magnets 432 may be disposed such that an S-pole thereof faces the gas injection unit 300 (of FIG. 1). For example, magnetic flux density at a desired level in the chamber 100 (of FIG. 1) may be formed by setting the polarity directions of the first magnet 431 and the second magnets 432 to be opposite to each other.

However, the polarity directions of the first magnet 431 and the second magnets 432 are not limited to the above description, and the first magnet 431 and the second magnets 432 may be disposed to have the same polarity direction in certain embodiments.

In example embodiments, the magnets 430 may not be disposed in at least some receiving parts 421/422. For example, referring to FIG. 5, the manufacturer (or the user) may adjust the magnetic flux density to an appropriate level by disposing a dummy member 440 instead of the magnet 430 to some receiving parts 421/422. FIG. 5 illustrates that the dummy member 440 is received in the second receiving part 422, but in contrast, the dummy member 440 may be received in the first receiving part 421 (of FIG. 4) in certain embodiments.

In example embodiments, the dummy member 440 may be formed of a nonmagnetic material (e.g., a nonmagnetic bar) or a material having greatly weak magnetism. For example, the dummy member 440 may be formed of Teflon.

Alternatively, some receiving parts 421/422 may be left vacant without even the dummy member 440. For example, some receiving parts among the plurality of receiving parts 421 and 422 which is provided to the magnet holder 420 may omit (e.g., not receive) the magnet 430. Through this, the strength of the magnetic field which is generated by the magnet assembly 400 may be variously and minutely/precisely adjusted.

Related substrate processing apparatuses have difficulty in freely changing disposition patterns and/or disposition numbers of magnets after a disposition pattern and/or a disposition number of magnets are once determined. However, the substrate processing apparatus 1 according to example embodiments may situationally and appropriately adjust disposition patterns of the magnet 430, disposition numbers of the magnets 430, or the like through the magnet holder 420 which is formed such that the manufacturer (or the user) may freely insert and/or pull out the magnets 430.

In example embodiments, the magnet assembly 400 may be formed by stacking a plurality of magnet holders 420, e.g., in a vertical direction. For example, referring to FIGS. 2 and 3, multiple magnet holders 420 may be disposed to be stacked on an upper part (e.g., on a top surface) of the base 410. In this case, a direction in which the plurality of magnet holders 420 is stacked may be a direction parallel to a direction of a height of the chamber 100 (e.g., a Z-axis/vertical direction). A plurality of magnets 430 may be inserted into the respective magnet holders 420. Accordingly, magnetic fields of the multiple magnet holders 420 may overlap each other to form the entire magnetic field of the magnet assembly 400.

In example embodiments, numbers of magnets received in two neighboring magnet holders 420 among the plurality of magnet holders 420 may be different from each other. For example, referring to FIG. 3, a lowest magnet holder of the magnet assembly 400 may receive magnets into all receiving parts, and another magnet holder disposed above the lowest magnet holder may receive magnets into only some receiving parts. Accordingly, in the plurality of magnet holders 420 stacked, e.g., in a vertical direction, the strength and the magnetic flux density of the entire magnetic field generated by the magnet assembly 400 may be minutely adjusted by variously adjusting the number of magnets disposed in each layer of the plurality of magnet holders 420.

In example embodiments, the magnet assembly 400 may further include guide members 450 for arranging and stacking the plurality of magnet holders 420. For example, referring to FIG. 3, the magnet assembly 400 may include a guide member 450 which has a pin shape and is inserted into each of two magnet holders 420 stacked side by side. Guide holes 423 into which the guide members 450 are inserted may be provided on upper surfaces and lower surfaces of the magnet holders 420. For example, the guide members 450 may be pins, bars, or rods (e.g., guide pins, guide bars, or guide rods), and each of the pins, bars, or rods may be inserted into the guide holes 423 of adjacent magnet holders 420 in a vertical direction with one end being inserted in a guide hole 423 formed on a top surface of a lower magnet holder 420 and the other end being inserted in a guide hole 423 formed on a bottom surface of a higher magnet holder 420.

In addition, a guide hole 411 into which a guide member 450 is inserted may be provided to the base 410 and/or the cover 460 which are disposed above and/or below a stack of the magnet holders 420.

The guide members 450 may be formed to be forcibly fit or bonded to guide holes 411 and 423. Accordingly, the guide members 450 may play a role in fixing the stacked plurality of magnet holders 420 to each other or fixing the stack of the magnet holders 420, the base 410, and the cover 460 to each other.

In example embodiments, the plurality of magnets 430 may be disposed, in identical patterns to or different patterns from each other, in the magnet holders 420 which forms respective layers of the magnetic assembly 400. FIG. 6A to FIG. 6C illustrate examples of disposing the plurality of magnets 430 in various patterns.

Referring to FIG. 6A, in the plurality of magnet holders 420 which is vertically stacked, while the magnets 431 and 432 are disposed into all of the first receiving part 421 and the second receiving parts 422 of a lowest magnet holder 420, the magnets 431 and 432 may not be disposed into the second receiving parts 422 of a magnet holder 420 disposed above the lowest magnet holder 420.

Alternatively, referring to FIG. 6B, in the vertically stacked plurality of magnet holders 420, while the magnets 432 may be disposed into the second receiving parts 422 of an intermediate magnet holder 420, the magnets 431 and 432 may not be disposed into the second receiving parts 422 of magnet holders 420 disposed above and below the intermediate magnet holder 420. As illustrated in FIG. 6B, a diameter dl of the first receiving part 421 may be larger than a diameter d2 of the second receiving part 422. Correspondingly, a first magnet 431 having a larger diameter than a second magnet 432 may be disposed into the first receiving part 421.

Alternatively, the plurality of magnet holders 420 which has different diameters of the first receiving part 421 may be stacked. For example, referring to FIG. 6C, a diameter d3 of the first receiving part 421 of the lowest magnet holder 420 may be larger than a diameter d4 of the first receiving part 421 of the magnet holder 420 disposed above the lowest magnet holder 420. For example, in the magnet assembly 400, two receiving parts 421a and 421b facing each other in the direction in which the magnet holders 420 are stacked (e.g., the Z-axis/vertical direction) may be formed to have different diameters from each other. Accordingly, a plurality of magnets having different sizes may be disposed in various ways.

However, various examples of stacking illustrated in FIG. 6A to FIG. 6C are merely a portion of various example embodiments according to the present disclosure. The manufacturer (or the user) may dispose the magnet 430 in various patterns with the magnet holder 420 according to the present disclosure in order to form a magnetic field at a desired level in the chamber 100.

FIG. 6A to FIG. 6C illustrate example embodiments in which three magnet holders 420 in total are stacked, but the number of the magnet holders 420 included in the magnet assembly 400 is not limited thereto. For example, the magnet assembly 400 according to example embodiments may be formed with one, two, four, or more magnet holders 420 stacked, e.g., in a vertical direction.

Furthermore, the magnet holder 420 according to example embodiments may be formed in various types having different numbers and positions of the second receiving parts 422. FIG. 7A to FIG. 7C illustrate the magnet holders 420 of such various types.

Referring to FIG. 7A, a first magnet holder 420a may have fourteen second receiving parts 422. A center of the first receiving part 421 and a center of each of the second receiving parts 422 may be spaced apart from each other at a first interval g1 in a radial direction.

Referring to FIG. 7B, a second magnet holder 420b may have fifteen second receiving parts 422. A center of the first receiving part 421 and a center of each of the second receiving parts 422 may be spaced apart from each other at a second interval g2 wider than the first interval g1 in a radial direction.

Referring to FIG. 7C, a third magnet holder 420c may have sixteen second receiving parts 422. A center of the first receiving part 421 and a center of each of the second receiving parts 422 may be spaced apart from each other at a third interval g3 wider than the second interval g2 in a radial direction.

The magnet assembly 400 according to example embodiments may include at least one of first through third magnet holders 420a, 420b, and 420c which are illustrated in FIG. 7A to FIG. 7C. For example, the magnet assembly 400 may be formed by stacking the magnet holder 420a, 420b, or 420c of at least one type of the first through third magnet holders 420a, 420b, and 420c.

For example, as described through FIGS. 2 through 7, a distance between the receiving parts 421 and 422, respective numbers, positions, sizes (e.g., diameters) of the receiving parts 421 and 422, a pattern in which the magnets 430 is disposed/arranged, or the like may be implemented to change in various ways in the magnet holder 420 which forms the magnet assembly 400 according to example embodiments.

Alternatively, in the magnet assembly 400 according to example embodiments, at least one of magnets received in the receiving parts 421 and 422 of the magnet holder 420 may be smaller than the receiving parts 421 and 422 in size (e.g., diameter). In this case, a guide ring GR for filling gaps between the magnets and the receiving parts 421 and 422 may be additionally disposed.

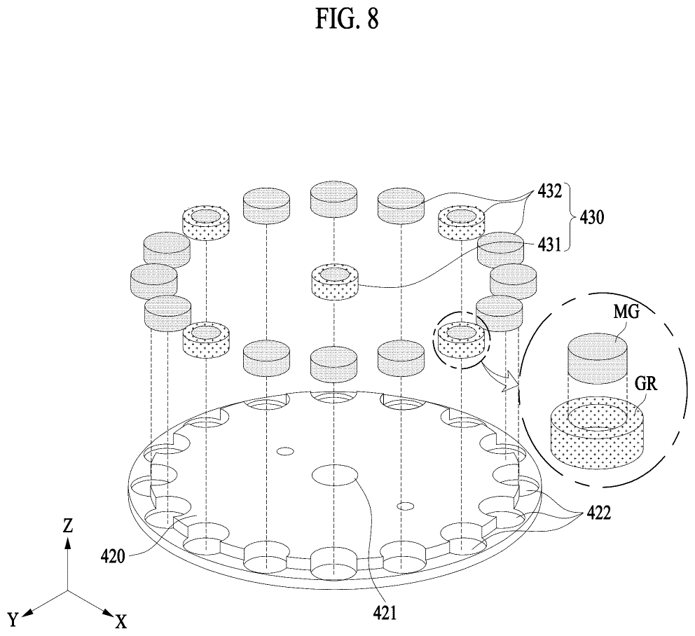

For example, referring to FIG. 8, at least one of the first magnet 431 and a plurality of second magnets 432 which are received in the magnet holder 420 may include a combination of a core magnet MG and the guide ring GR, which is not magnetic, for receiving the core magnet MG. In this case, a size (e.g., diameter) of the core magnet MG may be smaller than a size (e.g., diameter) of a corresponding one of the receiving parts 421 and 422. The guide ring GR may surround an outer circumferential surface of the core magnet MG and fill a gap between the core magnet MG and the corresponding one of the receiving parts 421 and 422 so that the core magnet MG is fixed at a position thereof in the receiving parts 421 and 422. At this point, the respective sizes of the receiving parts 421 and 422 may be equal to or different from each other. For example, all diameters of receiving parts in the magnet holder 420 may be the same, e.g., 26 mm, and one or more receiving parts may receive magnets having sizes corresponding to (e.g., substantially the same as or a little smaller or minimally smaller than) the one or more receiving parts, and core magnets MG which have smaller diameters (e.g., 20 mm) may be received in one or more other receiving parts in a state of being fitted to or inserted into one or more guide rings GR.

In example embodiments, the core magnet MG may be formed to have various sizes, and correspondingly, a size of the guide ring GR may be also variously changed so as to fill the gap between the core magnet MG and its corresponding one of the receiving parts 421 and 422. For example, at least one of the first magnet 431 and the plurality of second magnets 432 may be formed as an assembly structure of the core magnet MG and the guide ring GR in some embodiments. Through this, magnets having various sizes may be stably received in the receiving parts 421 and 422 by using the guide ring GR without changing the sizes of the receiving parts 421 and 422. Accordingly, since the magnets having various sizes may be disposed in combination by using the guide ring GR irrespective of a size of a receiving part of one magnet holder 420, the magnetic flux density may be minutely changed/controlled.

The manufacturer (or the user) may form the magnet assembly 400 by selecting an appropriate one of the magnet holders 420 of the various types described above and stacking the appropriate one in appropriate quantity. Accordingly, a formation position, density, or the strength of the magnetic field in the chamber 100 may be minutely adjusted.

Also, the manufacture (or the user) may implement various arrangement patterns of the magnets 430 by inserting the magnets 430 into only desired ones of the plurality of receiving parts 421 and 422 provided to the magnet holder 420. For example, when the magnet holder 420 according to example embodiments is used, since the number and a disposition pattern of the magnets 430 are easily changed to correspond to substrates of various types, shapes, or sizes, various types of substrates may be effectively processed with one substrate processing apparatus 1.

Also, while maximally securing flexibility of disposing the magnets 430, the magnet assembly 400 according to example embodiments may precisely and easily adjust the density of the magnetic field in the chamber, a formation position of a magnetic force line or magnetic field, or the like through the magnet holder 420 which may stably maintain a state in which the magnets 430 are spaced apart from each other.

For example, the substrate processing apparatus 1 according to example embodiments may form, at a desired position, the magnetic field in the chamber 100 at a desired level or of desired strength through the magnet assembly 400 of a stack type. Through this, a movement of an ion may be minutely controlled in an entire area including an edge of the substrate W. Accordingly, a distribution of plasma or ions may be controlled throughout the entire area of the substrate W. For example, directionality of the ion may sufficiently secured even in an edge area of the substrate W. Through this, efficiency and process speediness of a plasma process may be greatly increased.

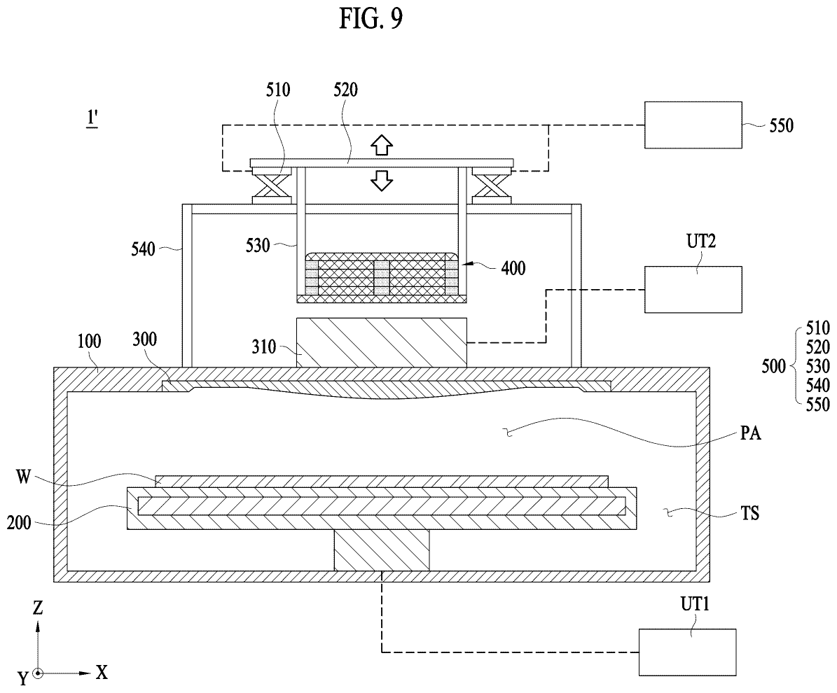

In another example embodiments, the magnet assembly 400 of a substrate processing apparatus 1′ may be formed to be movable with respect to the chamber 100. Hereinafter, the substrate processing apparatus 1′ including the magnet assembly 400 which is movable will be described with reference to FIG. 9.

FIG. 9 illustrates an example configuration of the substrate processing apparatus 1′ according to another example embodiment.

In example embodiments, the substrate processing apparatus 1′ may further include a position adjustment unit 500 configured to move the magnet assembly 400 with respect to the chamber 100. For example, referring to FIG. 9, the position adjustment unit 500 may be connected to the magnet assembly 400 which is disposed above the chamber 100, and an interval between the magnet assembly 400 and the chamber 100 may be changeable such that the interval is adjusted in a direction of a height of the substrate processing unit 1′ (e.g., a Z-axis/vertical direction in FIG. 9) through the position adjustment unit 500.

In an example embodiment described with reference to FIG. 9, all other elements other than the position adjustment unit 500 may have technical features identical to those of the substrate processing apparatus 1 of example embodiments described in FIGS. 1 through 8. For example, the magnet assembly 400 of the substrate processing apparatus 1′ may have a structure identical to that of the magnet assembly 400 which is described in FIGS. 1 through 8 except that the magnet assembly 400 of the substrate processing apparatus 1′is movable with respect to the chamber 100. Hereinafter, redundant descriptions the same as or similar to those of FIGS. 1 through 8 will be omitted, and characteristics associated with the position adjustment unit 500 will be described in detail.

In example embodiments, the position adjustment unit 500 may include a driver 510 (e.g., a motor) for generating a driving force for moving the magnet assembly 400, a moving frame 520, a connection frame 530 for connecting the moving frame 520 and the magnet assembly 400. For example, the connection frame 530 may be a frame positioned between the moving frame 520 and the magnetic assembly 400 such that the moving frame 520 and the magnetic assembly 400 are connected to each other through the connection frame 530.

In example embodiments, the driver 510 of the position adjustment unit 500 may be supported by a support frame 540 connected to the chamber 100. For example, referring to FIG. 9, the support frame 540 may be connected to an upper side/surface (e.g., a top surface) of the chamber 100, one or more drivers 510 may be disposed on the support frame 540. For example, the moving frame 520, the connection frame 530, and the support frame 540 may be frames formed of rigid bars. For example each of the moving frame 520, the connection frame 530, and the support frame 540 may be a bar or an assembly of bars.

In example embodiments, the driver 510 may adjust an interval between the magnet assembly 400 and the chamber 100 by moving the magnet assembly 400. For example, the driver 510 may move the magnet assembly 400 in a direction parallel to a direction of a height of the chamber 100 or in a vertical direction to adjust a position of the magnet assembly 400 so that a distance of the magnet assembly 400 from the chamber 100 and/or from the substrate processing space TS in the chamber 100 varies.

In example embodiments, the driver 510 may be a lab jack-type actuator configured to precisely move the moving frame 520 connected thereto. For example, the moving frame 520 may be a frame connected to (e.g., contact) the driver 510 and moved by the driver 510. However, a structure of the driver 510 is not limited to the above description. The driver 510 may be freely replaced with any type of actuator that may move the magnet assembly 400 connected thereto in a reciprocating manner in a predetermined direction. As used herein, when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

In example embodiments, the driver 510 may generate the driving force according to control by a driving controller 550. A user may adjust a position of the magnet assembly 400, the interval between the magnet assembly 400 and the chamber 100, a moving direction and a moving speed of the magnet assembly 400, or the like through the driving controller 550. As the position of the magnet assembly 400 is changed, a formation position of a magnetic field, strength of the magnetic field, a distribution of magnetic force lines may be changed in an inner space of the chamber 100. Through this, a movement of an ion in the plasma area PA may be controlled.

However, a structure of the position adjustment unit 500 which is illustrated in FIG. 9 is merely an example, and the structure of the position adjustment unit 500 according to example embodiments is not limited to an illustration. The position adjustment unit 500 may be implemented in any type that may move the magnet assembly 400 with respect to the chamber 100.

In order to avoid interference with a magnetic field generated from the magnet assembly 400, the moving frame 520, the connection frame 530, and the like which form the position adjustment unit 500 may be formed from a nonmagnetic material. However, materials of the moving frame 520 and the connection frame 530 of the position adjustment unit 500 is not limited thereto. Any material that may stably support and move the magnet assembly 400 may be applied without limitation.

For example, in a process of etching the substrate W through a plasma process, a concern of occurrence of a change over time in an ion path in the gas injection unit 300 or the plasma area PA may be present. For prevention thereof, a distribution of plasma or the density and trajectory of ions may be required to be continuously controlled in response to the change over time. The substrate processing apparatus 1′ according to example embodiments may adjust strength, a distribution, a formation position of a magnetic field in the chamber 100, or the like by adjusting the interval between the magnet assembly 400 and the chamber 100 in real time through the position adjustment unit 500 which may move the magnet assembly 400. Through this, the distribution of the plasma or the degree of the ion planarization may be controlled while the process is performed. Accordingly, an incidence angle of the ion may be controlled to maintain a predetermined direction (e.g., a direction perpendicular to an upper surface of the substrate W) in an entire area including an edge area of the substrate W.

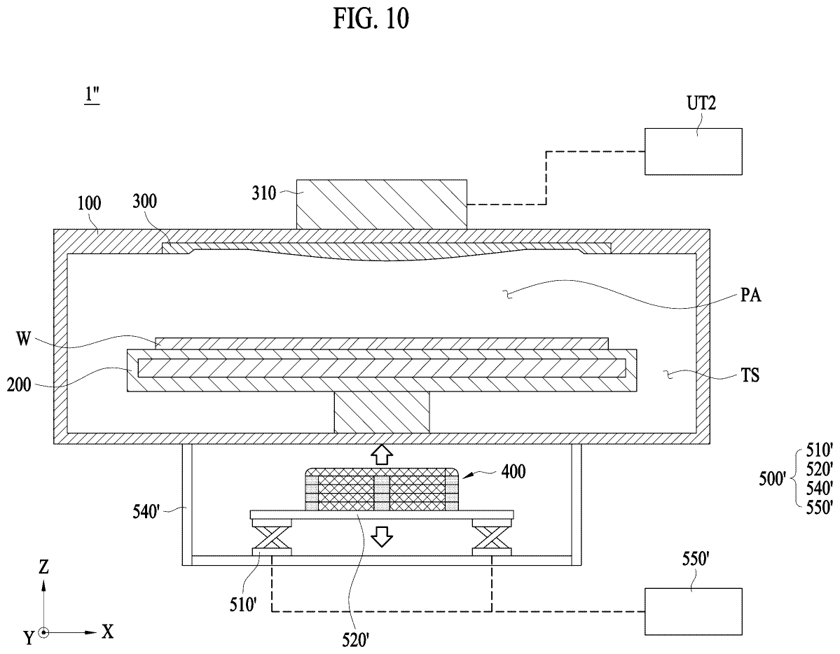

The magnet assembly 400 and the position adjustment unit 500 may be disposed at various positions outside the chamber 100. For example, referring to FIG. 10, the magnet assembly 400 and a position adjustment unit 500′ may be disposed below the chamber 100.

FIG. 10 illustrates an example configuration of a substrate processing apparatus 1″ according to another example embodiment.

In an example embodiment described with reference to FIG. 10, description of FIG. 9 may be referenced for all other features excluding positions of the position adjustment unit 500′ and the magnet assembly 400.

In another example embodiment, the magnet assembly 400 and the position adjustment unit 500′ may be disposed below the chamber 100. For example, referring to FIG. 10, a support frame 540′ and a driver 510′ of the position adjustment unit 500′ may be disposed below the chamber 100, and the magnet assembly 400 may be disposed above a moving frame 520′ connected with the driver 510′. The magnet assembly 400 may move, by driving of the driver 510′, in a direction toward a substrate or in a direction opposite thereto, e.g., upwards/downwards in a vertical direction. Accordingly, a formation position, strength, magnetic flux density of a magnetic field in the chamber 100, or the like may be changed.

The magnet assembly 400 of substrate processing apparatuses 1, 1′, and 1″ may include the plurality of receiving parts 421 and 422 which is formed such that the magnets 430 are inserted, thereby stably maintaining a mutual position (e.g., relative positions) of the plurality of magnets 430 in a state in which the plurality of magnets 430 is inserted in the receiving parts 421 and 422 and allowing a user to easily insert or replace the magnet 430.

In addition, since the substrate processing apparatuses 1, 1′, and 1″ according to example embodiments include the one or more magnet holders 420 which are stackable and/or stacked, e.g., in a vertical direction, the substrate processing apparatuses 1, 1′, and 1″ may provide a structure of the magnet assembly 400, in which the formation position and the magnetic flux density of the magnetic field in the chamber 100 may be minutely adjusted/controlled.

Also, the substrate processing apparatuses 1, 1′, and 1″ according to example embodiments may include position adjustment units 500 and 500′ for adjusting an interval between the magnet assembly 400 and the chamber 100, thereby controlling a distribution of plasma or a degree of ion planarization and constantly maintaining an ion incidence angle in an entire area of the substrate W.

Various example embodiments of the present disclosure have been described above in detail, but the scope of the present disclosure is not limited thereto. It will be apparent to those skilled in the art that various changes and modifications may be allowed within the scope of the technical spirit of the present disclosure. In addition, the above-described example embodiments may be implemented without a portion of elements thereof, and each of the example embodiments may be implemented in combination with another. For example, even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

What is claimed is:

1. A substrate processing apparatus comprising:
a chamber having a substrate processing space;
a substrate support disposed in the chamber and configured to support a substrate;
a gas injection unit disposed to be spaced apart from the substrate support and configured to supply a gas to the substrate processing space; and
a magnet assembly disposed outside the chamber and configured to form a magnetic field in the chamber,
wherein the magnet assembly comprises:
one or more magnet holders comprising a plurality of openings or indentations; and
a plurality of magnets received in at least one of the plurality of openings or indentations to maintain an interval between each other.

2. The substrate processing apparatus of claim 1, wherein the plurality of openings or indentations includes:
a first opening or indentation disposed on a central axis of the one or more magnet holders; and
a plurality of second openings or indentations disposed in a circumferential direction around the central axis.

3. The substrate processing apparatus of claim 2, wherein the plurality of magnets includes:
a first magnet received in the first opening or indentation; and
a second magnet received in one of the plurality of second openings or indentations and different from the first magnet in size.

4. The substrate processing apparatus of claim 3, wherein a polarity of a surface of the first magnet facing the gas injection unit is opposite to a polarity of a surface of the second magnet facing the gas injection unit.

5. The substrate processing apparatus of claim 2, wherein a diameter of the first opening or indentation is larger than a diameter of any one of the plurality of second openings or indentations.

6. The substrate processing apparatus of claim 1, wherein the magnet assembly further comprises a nonmagnetic bar received in the at least one of the plurality of openings or indentations.

7. The substrate processing apparatus of claim 1, wherein at least one magnet among the plurality of magnets comprises:
a core magnet having a size smaller than a size of an opening or indentation receiving the at least one magnet; and
a guide ring filling an interval between the core magnet and the opening or indentation.

8. The substrate processing apparatus of claim 1, wherein the one or more magnet holders include a first magnet holder and a second magnet holder that are coupled to be stacked.

9. The substrate processing apparatus of claim 8, wherein the plurality of magnets is disposed on the first magnet holder and the second magnet holder, and
wherein a first arrangement pattern of the magnets disposed on the first magnet holder is different from a second arrangement pattern of the magnets disposed on the second magnet holder.

10. The substrate processing apparatus of claim 8, wherein the magnet assembly further comprises a guide pin coupled to each of the first magnet holder and the second magnet holder.

11. The substrate processing apparatus of claim 8, wherein the magnet assembly further comprises:
a base supporting the first magnet holder and the second magnet holder; and
a cover vertically overlapping the first magnet holder and the second magnet holder stacked in a vertical direction.

12. The substrate processing apparatus of claim 8, further comprising a driver configured to move the magnet assembly in a direction parallel to a direction in which the first magnet holder and the second magnet holder are stacked.

13. The substrate processing apparatus of claim 1, further comprising a position adjustment unit configured to adjust an interval between the magnet assembly and the chamber.

14. The substrate processing apparatus of claim 13, wherein the position adjustment unit comprises:
a driver configured to generate a driving force for moving the magnet assembly;
a first frame disposed above the magnet assembly and configured to move by the driving force of the driver; and
a second frame connecting the first frame and the magnet assembly.

15. A substrate processing apparatus comprising:
a chamber having a substrate processing space configured to receive a substrate;
a magnet assembly disposed outside the chamber; and
a position adjustment unit configured to adjust an interval between the magnet assembly and the chamber,
wherein the magnet assembly comprises:
a plurality of magnets configured to form a magnetic field in the substrate processing space; and
one or more magnet holders configured to receive the plurality of magnets.

16. The substrate processing apparatus of claim 15, wherein the magnet assembly is disposed to be spaced apart from the substrate in a vertical direction, and
the position adjustment unit is configured to move the magnet assembly in the vertical direction.

17. The substrate processing apparatus of claim 15, wherein the plurality of magnets includes:
a first magnet disposed at a center of the one or more magnet holders; and
a plurality of second magnets disposed in a circumferential direction around the first magnet.

18. A substrate processing apparatus comprising:
a chamber having a substrate processing space;
a substrate support disposed in the chamber;
a gas injection unit disposed above the substrate support and configured to supply a gas to the substrate processing space; and
a magnet assembly disposed outside the chamber,
wherein the magnet assembly comprises:
a plurality of magnet holders stacked in a vertical direction; and
a plurality of magnets received in at least one of the plurality of magnet holders.

19. The substrate processing apparatus of claim 18, wherein the plurality of magnet holders includes:
a first magnet holder comprising a plurality of openings or indentations receiving the plurality of magnets; and
a second magnet holder stacked on the first magnet holder and comprising a plurality of openings or indentations receiving the plurality of magnets, and
the number of magnets received in the first magnet holder and the number of magnets received in the second magnet holder are different from each other.

20. The substrate processing apparatus of claim 18, further comprising a position adjustment unit configured to generate a driving force for moving the magnet assembly in the vertical direction.
